(19) United States
(12) Patent Application Publication
(10) Pub. No.: US 2015/0311359 A1
(43) Pub. Date: Oct. 29, 2015

(54) METHOD FOR MANUFACTURING A SOLAR CELL AND SOLAR CELL OBTAINED THEREWITH

(71) Applicant: M4SI B.V., Waalre (NL)

(72) Inventors: Johannes Reinder Marc Luchies, Waalre (NL); Robertus Adrianus Maria Wolters, Eindhoven (NL); Klaas Heres, Berkel en Rodenrijs (NL)

(21) Appl. No.: 14/424,844

(22) PCT Filed: Aug. 29, 2013
(86) PCT No.: PCT/NL2013/050623

§ 371 Date: Feb. 27, 2015

(30) Foreign Application Priority Data
Aug. 29, 2012 (NL) 2009382

(51) Int. Cl. H01L 31/0224; H01L 31/054; H01L 31/032; H01L 31/0445; H01L 31/0272; H01L 31/048; H01L 31/072

(52) U.S. Cl. CPC H01L 31/022425; H01L 31/048; H01L 31/054; H01L 31/022458; H01L 31/072; H01L 31/0445; H01L 31/0272; H01L 31/0322

(57) ABSTRACT

The method of manufacturing a solar cell, comprising the steps of providing a solar cell device comprising a semiconductor body (10) and having a first side (11) and an opposed second side (12), which first side is intended for capturing incident light and which second side is intended for assembly to a carrier, which solar cell device comprises a first contact region (13) in the semiconductor body (10) at one of the first (11) and the second side (12); applying an optically transparent structure (22) of electrically insulating material to at least one of the sides (11, 12) of the solar cell device, which structure is patterned to form an aperture to the first contact region (13); providing a contact structure (41, 42, 43) of electrically conducting material in said aperture by means of electrochemical deposition.

### FIELD OF THE INVENTION

The invention relates to a method of manufacturing a solar cell, comprising the steps of:

Providing a solar cell semi-manufactured device comprising a semiconductor body and having a first side and an opposed second side, which first side is intended for capturing incident light and which second side is intended for assembly to a carrier, which semiconductor body comprises a first contact region, and

Providing an electrically conducting structure on top of said first contact region.

The invention also relates to a solar cell comprising a solar cell device comprising a semiconductor body and having a first side and an opposed second side, which first side is for capturing incident light and which second side is for assembly to a carrier, which semiconductor body comprises a first contact region, on top of which an electrically conducting structure is present.

The invention further relates to manufacturing equipment for the provision of such an electrically conducting structure.

### BACKGROUND OF THE INVENTION

Solar cells are large area semiconductor devices, which convert radiation (i.e. sunlight) into electricity. The most common silicon solar cells have doped regions on both sides of the solar cells. For p-type cells this achieved by doping the front side with phosphorus, and the rear side is doped by aluminum. For n-type cells this accomplished by doping the front side with boron and the rear side with phosphorus.

Another important class of solar cells is the group of back-contacted solar cells, meaning that both ohmic contacts to the two oppositely doped regions of the solar cells are contacted on the second, i.e. rear surface of the solar cell. This class of solar cells reduces shadowing losses caused by the front metal contact grid on standard solar cells. Suitably, an emitter is provided on the front or first side (the terms side and surface are hereinafter used exchangeably) of the semiconductor substrate (hereinafter also referred to as substrate). Furthermore, in order to optimize the collection of incident radiation, the first side of the semiconductor substrate may be texturized, and provided with an antireflection coating.

To contact the doped regions of the solar cell typically, use is made of screen-printing, for instance of a silver paste, in order to define said conductors on the first side of the substrate, as well as to define the said conductors on the second side. Herein a metal paste, a silver or aluminum based paste is printed and thereafter converting into metal in a sintering “firing” step. Screen-printing appears to meet following requirements of solar cell manufacture. First of all, screen-printing does not require the provision of a separate masking step. Secondly, at least some screen printing pastes are able to remove any material present on top of the substrate, such as an antireflection coating.

Therewith it simplifies processing. A third reason is its suitability for use on a texturized and therefore non-planar substrate. A final reason is that the silver of the screen-printing paste forms an acceptable contact with the silicon substrate and does not diffuse into the silicon substrate.

However, screen-printing has certain major disadvantages. First, the thin fingers of the conductors, when formed by the screen-printing process may be discontinuous since the fingers formed using a metal paste do not always agglomerate into continuous interconnecting line during the high temperature annealing process. Second, porosity present in the fingers formed during the agglomeration process results in greater resistive losses, leading to more material usage. Third, due to the relatively thin substrate thicknesses commonly used in solar cell applications, such as 200 micrometers and less, the act of screen printing the metal paste on the substrate surface can cause physical damage, and the required annealing may give rise to high intrinsic stresses in the solar cell. This can cause breakage of the formed metallized features, warping of the thin solar cell substrate, and/or delamination of the metallized features from the surface of the solar cell substrate.

High temperature processes also limit the types of materials that can be used to form a solar cell due to the breakdown of certain materials at the high sintering temperatures. Forth, and most important, the screen-printing material that allow subsequent firing is usually silver, which is extremely expensive for application in solar cells.

Electrochemical deposition, of which electroless deposition and/or electroplating are best-known examples, is considered as an interesting alternative, and has been proposed regularly for the deposition of conductors at the rear side. A requirement to its use is some form of patterning, since the deposited material will begin growing on an electrically conductive surface and thereafter expand to any surrounding open space. Various ways have been proposed to create the pattern prior to electrochemical deposition, for instance the use of a photosensitive resist (i.e. photoresist), and the printing of a barrier. The resist and the barrier need to be removed after the electrochemical deposition process. This has the disadvantage that residues may remain Particularly when used on the first side of the substrate, that is intended to capture any incoming irradiation, such residues are undesired, as they will reduce the efficiency of the resulting solar cell.

WO85/02939 discusses for instance the use of electroplating. In order to limit the spread of electroplated material also known as ghost-plating, this application proposes the use of a separate masking plate provided with local apertures. Lines running through the masking plate are present so as to provide the chemicals needed for electroplating, particularly an electrolyte solution. The application makes use of expensive photo-resist that is subsequent to the plating steps again removed leading to high cost.

US2011/0021023A1 furthermore provides an improved process for patterning an antireflection coating typically present on the first side of the substrate. This improved process comprises the use of a surfactant, such that a mask layer deposited by means of ink jet printing can be formed in a stable manner on the antireflection coating. This mask layer is removed again after patterning of the antireflection coating. The application mentions that any subsequent deposition process may be carried out with any suitable deposition technique, including electroplating. However, an antireflection coating is relatively thin, in comparison to any conductors. Therefore, when subsequently depositing any metal, it is not apparent how to define conductors with an appropriate shape and suitably a desired orientation. Particularly, when electroplating any conductor maskless, the conductor will spread out to obtain a hemi-spherical shape. Such a shape tends to cover more surface area than desired, leading to a loss of area transparent for irradiation and thus to an efficiency loss. Beyond that, it is not possible to define conductors extending laterally along the surface. Furthermore, such a shape may lead to short-circuits between neighboring terminals when applied on the rear side.

### SUMMARY OF THE INVENTION

It is therefore an object of the invention to provide an improved process of manufacturing solar cells using electrochemical deposition that is cost effective due to a limited number of process steps and also substantially prevents manufacturing artifacts such as residues and/or ghost plating.

It is another object of the invention to provide a solar cell with electrochemically deposited conductors without manufacturing artifacts such as residues and/or ghost plating.

It is a further object of the invention to provide manufacturing equipment suitable for use in said method.

According to a first aspect of the invention, a method of manufacturing a solar cell is provided, for a solar cell that comprises a solar cell device and an optically transparent structure, through which optically transparent structure a contact structure extends to a first contact region in a semiconductor body of the solar cell device. This method comprises the steps of:
Providing the solar cell semi-manufactured device comprising a semiconductor body and having a first side and an opposed second side, which first side is intended for capturing incident light and which second side is intended for assembly to a carrier, which solar cell device is provided with a passivation layer on on at least one of the first and the second side;
Applying the optically transparent structure of electrically insulating, curable polymer material to the passivation layer on at least one of the sides of the solar cell device, and curing the polymer material, which structure is patterned to form an aperture to the first contact region, and is a protection of the solar cell device, and
Providing the contact structure of electrically conducting material in said aperture by means of electrochemical deposition.

According to a second aspect of the invention, a solar cell is provided comprising a solar cell device provided with a semiconductor body with a first contact region and a passivation layer thereon, which solar cell device is provided with a first side and an opposed second side, which first side is for capturing incident light and which second side is for assembly to a carrier, wherein the solar cell further comprising a contact structure connected to the first contact region, wherein a patterned optically transparent structure of insulating, cured polymer material is present on the passivation layer on at least one of the first and second side of the solar cell device, which contact structure extends through the patterned optically transparent structure through the passivation layer and is electrochemically deposited.

According to the invention, an optically transparent structure is applied on the passivation layer on the first side and/or the second side of the substrate. This structure defines a space for the subsequent electrochemical deposition of conductors. It allows the deposition of a plating base selectively. This optically transparent is an integral part of the resulting solar cell.

The inventors according to the present invention have observed that the electrochemical deposition at the first side particularly results in performance degradation of the cell. It turned out that this cell performance degradation was due to ghost plating, i.e. growth or deposition of electrically conductive material on areas where such material is not desired and was not expected. A primary reason for the ghost plating turns out to be that the underlying layer, particularly a passivation layer such as silicon nitride is not free of defects, i.e. contains holes, voids, gaps and the like on a microscopic level.

With the provision of an optically transparent structure according to the invention, this ghost plating is prevented. Moreover, residues are not formed either, because the transparent structure is not removed.

The term ‘optically transparent structure’ refers in the context of the invention, to any layer or body, which is suitable for transmitting irradiation, particularly from the solar radiation, either directly or indirectly. It comprises a polymer material, rather than an inorganic material such as silicon nitride. A relevant additional property is that the structure does not degrade chemically due to incoming radiation, and particularly over the foreseen long lifetime of a solar cell. This requirement is not only relevant at the first side, but also at the second side of the solar cell device, where radiation ends up after transmission and/or reflection through and/or along the semiconductor body. A photosensitive or UV-sensitive resist is therefore unsuitable as a material for the optically transparent structure. The cured polymer material is therefore preferably UV-insensitive, i.e. it does not contain any UV-sensitive compounds or groups (i.e. initiators), which are able to initiate a chemical reaction upon (repeated) irradiation with UV. Such chemical reactions are for instance cross-linking reactions, that may decrease adhesion to an underlying layer. However, decomposition reactions are not excluded either.

More specifically, use is made of polymer materials that may be cured in a heat treatment, and/or be self-curing. The heat treatment may be carried out separately, or be part of the deposition process.

Various polymers are suitable as the polymer material of the optically transparent structure, including addition polymers and so-called condensation type polymers. Suitably, the polymer is provided with functional groups such that a cross-linked three-dimensional network may be formed, for instance polysiloxanes, polyesters, polyimides and polyacrylates, polymethacrylates, such as PMMA.

The optically transparent structure of the invention may be provided in various thicknesses according to different embodiments of the invention. The thickness may vary from 1 nm to 30 microns, and be a very thin with a nanometer range thickness, or be thick with a micrometer thickness, or be a combination of both. The optically transparent structure may be provided as a single layer, but also as multiple layers. The use of multiple layers allows the use of different materials and different application techniques for consecutive layers. A first layer is suitably applied in a coating process, such as spin-coating, web-coating or the like. For the deposition of a further layer, use could be made of a moulding process alternatively. Moreover, in order to define specific channels, use could be made of printing processes, such as screen or inkjet printing.

The optically transparent structure may extend to the second side of the substrate. In one specific embodiment, it forms an encapsulation. This appears beneficial for the stability of the solar cell.

Moreover, such an encapsulation allows complete protection against chemicals used in the plating process and prevents any unwanted ghost plating. Alternatively, the optically transparent structure could be present at the second side only

The optically transparent structure may further include one or more functional additives for enhancing optical transmission. Examples are for instance silver or gold particles and/or rare earth materials like Lanthanum. The incorporation of such functional additives could be used as an alternative or as an addition to the provision of texture at the front side of the semiconductor substrate. Their foreseen function is light scattering. The particles are preferably nanoparticles or nanostructured materials, for instance deposited with nano-imprint lithographical techniques, and having dimensions in the nanometer range. Reference is made to K. R. Catchpole and A. Polman, Optics Express 16 (2008), 21793-21800, which refers to experiments with particles embedded in air, silicon nitride and silicon. This articles is incorporated herein by reference.

In a first embodiment, the optically transparent structure comprises a first layer that is relatively thin and particularly acts as a sealing material for any underlying layer, so as to prevent any ghost plating. The thickness of this first layer may be limited to less than 0.2 microns, more preferably at most 0.1 microns, and suitably less than 80 nanometer, and preferably less than 50 nanometer and more preferably less than 20 nanometer, up to a limited thickness in the range of 1 to 10 nm, and is intended to act to fill any gaps and voids in the underlying layer and act as a protective sealing. The first layer is suitably a substantially conformal layer, even on a non-planarized substrate when applied in liquid form. Thereto, the material of the first layer adheres suitably well on the underlying passivation layer. More particularly, the material would wet the underlying layer, and most preferably would be able to interact with the material of the underlying layer, for instance to form hydrogen bonds.

In a suitable implementation, the first layer is patterned after its deposition using a beam-shaped irradiation source, more particularly a laser source. The preferred limited thickness has the benefit that both the optically transparent structure and the underlying passivation layer may be patterned in a single apparatus. For instance, the patterning of both layers could be carried out in a single step. Alternatively, use could be made of a plurality of consecutive laser beam passes in the same apparatus, for instance two consecutive beam passes. The application of a plurality of laser beam passes allows the use of different wavelengths for different layers, which allows better control and further optimization of dimensions and the process. Good results have been obtained in using a wavelength in the near-UV range, more suitably in the UV-B range as defined in ISO-standard 21348. An excimer laser or a solid state laser is for instance suitable for emission of such light. Furthermore, the optically transparent structure may comprise a second layer on top of the first layer. This second layer may have a larger thickness and is intended to constitute walls so as to define a space within with the contact structure and any further conductor means may be deposited.

One advantage of this creation is that the first and second layer may be deposited separately, i.e. comprising different materials, using different application processes and having different patterns.

For instance, the second layer may be deposited using a printing technique. The first layer and/or an additional intermediate layer may further be selected so as to obtain an appropriate adhesion.

Materials therefore are known per se in the art as primers. The second layer may have a thickness up to 50 or even 100 microns.

A further advantage of an optically transparent structure with a first and a second layer is that the cross-sectional surface area of any spaces between layer portions may be smaller in the first layer than in the second layer. Said cross-sectional surface area of the space in the first layer may for instance be less than 50%, less than 25% or less than 10% of the cross-sectional surface area of the space in the second layer. The benefit hereof is a corresponding reduction in the size of the first contact region, resulting in less recombination of charge carriers. Such small contact region is therefore beneficial for cell efficiency. Rather than using a first and a second layer, merely a second layer is used according to another embodiment of the invention.

In one further implementation, the second layer may be deposited according to a pattern characterized by protruding walls. It thus defines local walls rather than being continuous over the full surface. The protruding walls are designed so that conductors may be grown and/or deposited between a pair of walls. An important advantage hereof is that such protruding walls may expand and contract relative to each other during heating and cooling phases in operation of the solar cell device, also known as thermal cycling. If the structure is continuous, thermal cycling may give rise to failure due to a differential expansion relative to the semiconductor body. This occurs, in that the thermal coefficient of expansion of silicon is much lower than that of polymers, leading to significant stresses on contact structures particularly at the edge of a solar cell device, but also in cavities between sections of a texturized side of a semiconductor body.

In a further embodiment, the optically transparent structure may have a thickness, which substantially planarizes a first texturized side of the solar cell device. First sides of the solar cell device are typically texturized so as to optimize the capturing of incoming radiation. The advantage of a substantially planarized substrate is that it may be used as a carrier for further processing on the opposed second side.

In such an embodiment, it appears suitable to use a layer of a compliant material as part of the optically transparent structure, for instance, but not limited thereto, as a first layer. Most preferably a material with a relatively large coefficient of thermal expansion is used. Such a material is suitable for reducing stresses due to thermal cycling. Particularly with an optically transparent structure of larger thickness than the semiconductor substrate and with metal conductors running parallel to the substrate, and being coupled through contact structures to the semiconductor substrate at different locations, there is a risk for failure due to thermal cycling, i.e. differences in thermal expansion. Compliant materials are known per se, for instance in the field of semiconductor packaging. One example is for instance polydimethylsiloxane (PDMS) with a thermal coefficient of expansion of 3.1×10−4 K−1. The Young modulus of PDMS can range between 0.7 and 3.5 MPa, depending on the mixing ratio, curing temperature, and baking time. The Young modulus of PDMS is lower than silicon-based or metallic materials and allows for it to undergo large elastic deformations. Modification of PDMS so as to tune its adhesion properties is well-known in the art. Alternatively or additionally, poly-acrylates, poly-methacrylates, such as poly-methylmethacrylates, polyimides, epoxides, polyvinyl alcohols, polycarbonates, polyamides, polyesters such as those for liquid crystalline applications may be used.

In again an alternative embodiment, the optically transparent layer is provided as a layer stack, and layers are selectively removed at the end of the manufacture. Such a selective removal, for instance with the help of sacrificial layers, allows for removal of any top layer that is damaged in the course of processing, i.e. so as to reduce transparency of the surface.

One most suitable embodiment of a passivation layer herein comprises silicon nitride. The passivation layer may further comprise silicon oxide and/or silicon oxynitride. The silicon nitride may further be used as an anti-reflection coating. Suitably, because of the deposition of the optically transparent structure, the silicon nitride may be deposited as a low-quality layer, for instance by means of PECVD rather than by means of LPCVD. PECVD may be applied at a lower temperature and quicker than LPCVD.

In another embodiment, the passivation layer and/or the semiconductor body may comprise an amorphous semiconductor layer. This amorphous layer may be integrated in the semiconductor substrate, but is suitably deposited onto a semiconductor substrate. Solar cell types making use of such an amorphous layer are known per se as bifacial cells and HIT cells, wherein HIT is an abbreviation for Hetero junction with a Intrinsic Thin layer. In the latter type, the emitter is defined as a heterojunction and is made of two different materials, such as for instance mono-crystalline silicon and amorphous silicon or a III-V substrate and an amorphous silicon layer. The amorphous silicon layer is most suitably present as a stack of an intrinsically doped layer and a layer doped with charge carriers of a first conductivity type. The amorphous silicon layer may be present either on both the first side and the second side, or only on one side, such as the first side. The amorphous silicon layer turns out to be a good passivation layer and creates a pn-junction, and leads to an increased band gap, i.e. to provide a band off-set. Most suitably, a transparent conductive layer such as ITO is provided for charge injection.

In an alternative or additional embodiment, the solar cell device is of the so-called PERC type. The PERC type solar cell device comprises a passivation with an oxide or oxynitride or aluminium oxide. Subsequently a metal contact is defined to a substrate diffusion underlying said passivation, suitably with aluminium. The PERC type cell may be of the n-type but is suitably based on a p-type substrate.

The method of the invention has the advantage that it may be applied at low temperature, in comparison to prior art screen-printing methods for the deposition of conductors. Such low temperature regime is better compatible with the presence of the amorphous layer. As a consequence thereof, the risk of unintended recrystallization of the amorphous layer is reduced significantly.

The optically transparent structure may be applied either on the first side, or on the second side or on both sides. In case of application on the first side, the structure is preferably provided with channels for guiding of conductors that run largely or substantially parallel to the first side. In case of application on the second side, very useful application is foreseen in combination with a so-called inter-digitated back contact (IBC) definition, also known as an IBC cell. Alternatively, the cell may be of the HJBC-type, i.e. a hetero-junction back-contact cell. In case of application on both sides, a substrate encapsulation is provided.

In accordance with one suitable embodiment of the invention, a first terminal is coupled to the contact structure through conductor means provided with conductors running over the optically transparent structure or in channels within an optically transparent structure. The optically transparent structure and the electrical conductor may herein also extend from the first side to the second side of the solar cell device.

In an alternative embodiment, conductor means are present between the contact structure and a further contact of the solar cell device. This further contact is suitably present at the second side of the solar cell device. The conductor means herein comprises an electrical conductor that runs over the optically transparent structure or in channels within the optically transparent structure. More specifically, the optically transparent structure with the electrical conductor extend from the first to the second side of the solar cell device.

This extension of the electrical conductor and the transparent structure further allows the addition of more functionality to the solar cell while maintaining robustness and a proper isolation.

Particularly, the provision of the electrical conductor by means of electrochemical deposition such as electroplating ensures a connection with a low electrical resistance. This extension is also suitable for solar cells of the thin-film type, wherein the top electrode of a first subcell needs to be connected to a bottom electrode of a further subcell. The extension is further deemed beneficial for MWT-type solar cells.

Most preferably, the optically transparent structure is present between said conductors and the semiconductor body.

One advantage of this effective isolation of the conductors from the semiconductor body is a significant reduction of the risk for metal diffusion into the semiconductor substrate. This reduction of metal diffusion is beneficial for lifetime of the solar cell. Moreover, due to the reduction, a considerably larger number of materials turns out suitable for the electrochemical deposition process. Copper, a well-known and suitable conducting material, diffuses quickly through the silicon substrate, therewith damaging junctions, leading to malfunctioning of the solar cell.

The surface of the optically transparent structure, and particularly a channel defined therein, forms moreover an appropriate frame for deposition of additive layers. Such additive layers include a barrier layer, a further plating base, and adhesion layers. Suitable barrier materials are for instance nickel, titanium nitride, tantalum nitride and the like. Suitable plating bases are typically electrically conducting materials, which are preferably deposited by means of plating, printing or coating. Suitable materials may also include electrically conducting polymer materials, such as an aqueous dispersion of polyethylene-3,4-thiophene in polystyrene sulphonic acid (PEDOT/PSA).

The provision of the patterned optically transparent structure may be embodied as a patterned deposition process, such as with inkjet printing or screen-printing, or alternatively be embodied as a coating process for provision of the structure, which is subsequently patterned. It will be understood that the combination is not excluded, i.e. the provision of the structure in a printing process, which is thereafter completed by means of an additional patterning step, for instance for fine tuning, or shape improvement of side walls of any apertures.

The definition of apertures into the optically transparent structure is suitably carried out by local heating, for instance with a beam shaped source, such as a laser source, or in contact with a hot surface. The local heating is understood to result in local evaporation of the material, though other mechanisms (such as initiating a reaction with volatile reaction products) is not excluded. A subsequent removal, dissolution and/or cleaning step of the aperture may be done. Alternatively, use may be made of a material comprising a photo-initiator, such that the transparent structure can be patterned without such local heating. However, such optically transparent materials with a photo-initiator are relatively expensive and may reduce the lifetime of the solar panel by UV degradation.

Rather than using electrochemical deposition processes for the definition of contact structures and for the provision of conductors running more or less parallel to the substrate surface, i.e. as interconnects to individual contact structures, another deposition process could be applied for the formation of said conductors. For instance use can be made of printing processes within any channels defined in the optically transparent structure. If needed, any printed conductor may be strengthened with any subsequent electrodeposition process.

In one suitable embodiment, the first side of the solar cell device is textured. Such a texture is suitably applied for increasing the coupling of light into the semiconductor body. The method of the invention is very suitable for use at the first, front side of the solar cell device. First of all, particularly in the embodiment of the use of beam-shaped radiation, appropriate holes and cavities may be created into the transparent structure, notwithstanding its—at least partially—oblique orientation on the textured substrate surface. Secondly, the remaining transparent structure does not need to be removed; thirdly, there is no need for the provision of additional support layers, such as masks that need to be removed, but after removal may nevertheless give rise to differences in optical transmission behavior, for instance as a consequence of residues, easy attachment of aerosols and/or other airborne particles.

Most advantageously, in case of such textured first side, the optically transparent structure is deposited so as to substantially planarized the first side. Therewith, the transparent structure may be a support structure for the thin and fragile semiconductor substrate, and may even be used as a carrier during subsequent processing at the second, rear side.

In a further step of the method, conductor means may be provided that electrically couple the contact structure to at least one terminal of the solar cell. Such conductor means may extend onto the first side, for instance in channels with the optically transparent structure, and particularly the second layer thereof.

According to a further aspect of the invention, manufacturing equipment is provided for use in the method of the invention. Such manufacturing equipment comprises:
A coating apparatus for coating at least a first side of a semiconductor substrate with an electrically insulating transparent material;
A heating device for curing said insulating material to define an optically transparent structure;
A chuck for supporting a second side of said semiconductor substrate;
An irradiation source for the locally irradiating said optically transparent structure so as to define at least one aperture therein;
An electrochemical deposition apparatus for deposition of electrically conducting material in said aperture.

It will be understood that features discussed in relation to one aspect of the invention apply to another aspect as well.

### BRIEF DESCRIPTION OF THE FIGURES

These and other aspects of the invention will be further elucidated with reference to the Figures, wherein:

FIG. 1-4 show consecutive steps of an embodiment of the method of the invention in cross-sectional diagrammatical views;

FIG. 5 shows a cross-sectional diagrammatical view of a second embodiment of the invention, and;

FIG. 6 shows a cross-sectional diagrammatical view of a third embodiment of the invention.

### DETAILED DESCRIPTION OF PREFERRED EMBODIMENTS

The figures are not drawn to scale and merely intended for illustrative purposes. Equal reference numerals in different figures refer to like or equal parts. Particularly, the semiconductor body 10 shown in the following figures is shown as being provided with merely a single metal contact structure 20 on the front. However, in practice, a plurality of metal contact structures will be applied to corresponding contact regions in the body 10. It is observed that the terms front side will be applied for the first side 11, if and where the first, front side 11 can be distinguished from the second, rear side 12. The semiconductor body 10 will also be referred to as a semiconductor substrate or a substrate. However, the term ‘body’ is intended to cover embodiments wherein the substrate does not contain semiconductor material, or wherein additional semiconductor layers are provided on the semiconductor substrate. The term solar cell device, or semi-manufactured solar cell device is intended to refer to the layer or stack of layers jointly responsible for the conversion of light into electrical energy. This device is typically a diode device, for instance a p-i-n type photodiode, or p-n-photodiode, or a stack of photodiodes. It is typically the result of so-called front-end processing, prior to definition of the back-end of conductor patterns. The solar cell device may further be a so-called thin film device, wherein the semiconductor body is present on an insulating substrate. However, a device with a semiconductor substrate is preferred.

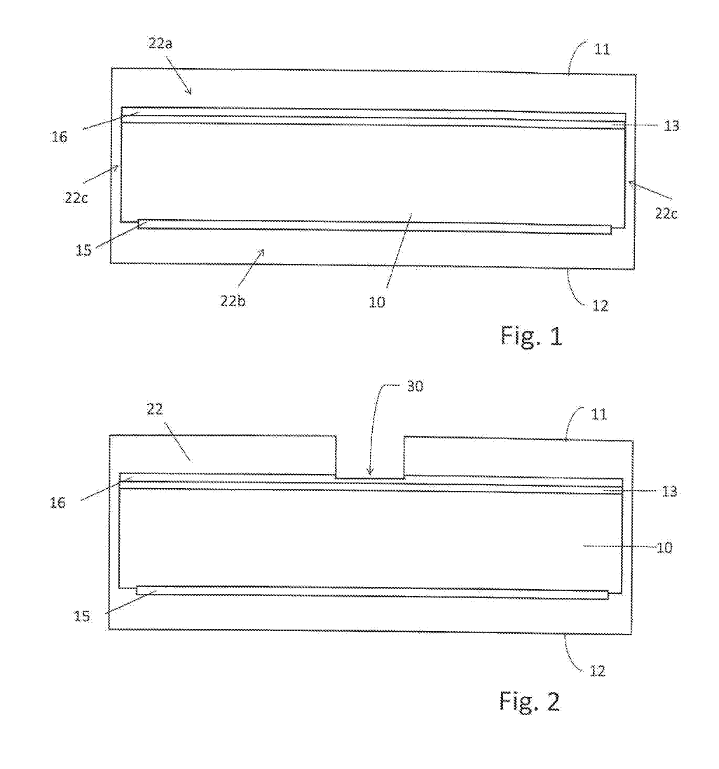

FIG. 1-4 show consecutive steps of an embodiment of the method of the invention in cross-sectional diagrammatical views. The semiconductor substrate 10 of this example is a multi-crystalline silicon substrate. While silicon substrates constitute the best available compromise between manufacturing costs and quality, it is not excluded that alternative substrates are used.

Such alternative substrates could be other silicon substrates like mono-crystalline p- or n-type, mono-cast (also known as pseudo mono) or thin film substrates for instance made of III-V materials, but more likely incorporate one or more layers of a different material as known to the skilled person. The semiconductor substrate is doped with a dopant of the first conductivity type, which is in this example p-type.

FIG. 1 shows a semiconductor substrate 10 with a first side 11 and a second side 12. The first side 11 and optionally the second side 12 typically have been texturized in advance of doping processes. The first side 11 is the side that is intended for receiving irradiation during use. The second side 12 is the side intended for assembly to a carrier. A first contact region 13 is present at the first side 11 of the substrate 10, which is more precisely a diffusion region. In this embodiment, the first contact region 13 extends substantially along the complete substrate surface at the first side 11. This is however not necessary. Alternative configurations, such as those with a selective emitter, are known per se to the skilled person. A passivation layer 16, suitably comprising silicon nitride, is present on the first side 11, and is deposited by chemical vapor deposition (CVD) as known to the skilled person. Alternative materials are not excluded. Further layers may be present between the exposed first contact region 13 and the passivation layer 16. The passivation layer 16 typically also functions an antireflection coating.

In a suitable embodiment, a layer of the same material as the passivation layer 16, suitably a layer of silicon nitride, is also present on the second side 12 of the substrate. This is advantageous for proper adhesion, if—as will be shown with reference to FIG. 2—the optically transparent structure extends both on the first side 11 and on the second side 12. However, such extension is not deemed necessary.

In accordance with one embodiment of the present invention, the first contact region 13 is a n+-doped region. At the second, rear side 12, a second contact region 15 is created. This second contact region 15 is for instance formed by deposition of an aluminum layer, for instance by screen printing, and subsequently sintering (firing) the aluminum as a dopant into the silicon. The creation of such second contact region 15 is deemed beneficial so as to obtain a good contact to the substrate 10—particularly the surface field created therein—over a maximum surface area. It will however be understood that alternative configurations and options for contacting at the rear side 12 are possible.

FIG. 2 shows the semiconductor substrate 10 after a second stage in the processing. Herein, an optically transparent structure 22, with portions 22a, 22b, 22c of electrically insulating material is applied on the substrate 10. In the shown embodiment, this transparent structure is present on the texturized first side 11 (portion 22a). Moreover, the optically transparent structure 22a-c further extends around substrate side edge 14 (portion 22c) to the second side 12 of the substrate 10 (portion 22b).

The optically transparent structure 22 is deposited by any suitable technique, for example spin coating, flowing, spray coating, screen printing, ink-jetting or by a dipping procedure in a solution, and/or by a moulding operation. It may be applied as a single layer, but also as multiple layers.

Coating and dipping techniques appears advantageous, in that the substrate 10 may be covered even if the first side 11 of the substrate 10 is not laid down on a substrate table (i.e. chuck). After deposition of the transparent structure 22, it is cured for stabilization purposes and is formed of a thickness less than 50 micrometers.

In a first embodiment, the optically transparent structure may be deposited in a thickness of 1 micrometer and 30 micrometers, preferably in the range of 1-20 micrometer. Such a thickness is for instance suitably to extend beyond any surface topology, for instance as a result of texturing. The conductor is thereafter applied in spaces defined within this optically transparent structure.

In an alternative embodiment, the optically transparent structure may have a thickness in the range of less than 100 nanometers, such as less than 50 nm or more preferably less than 20 nm, for instance 1 to 10 nm The use of a thin optically transparent structure is particularly suitable as a protection against ghost plating. Such a structure is suitably patterned by means of heating with a patterned beam, such as a laser beam, for instance with a wavelength in the UV-range.

In a further embodiment, the optically transparent structure comprises both a layer with a small thickness in the nanometer range, and a further layer or layer stack with a thickness in the micrometer range. Combination of both layers has the advantage that the first layer with a nanometer range thickness can be used to substantially cover and protect the underlying surface, whereas the second layer with a micrometer range thickness provides guidance for the definition of conductors. Moreover, the first layer is suitably patterned with beam-shaped irradiation, whereas the second layer is more suitably applied in a printing process.

In case that the structure is deposited as a sequence of layers, curing may be carried out after each layer deposition separately or merely at the end, while suitably applying a drying treatment after deposition of a separate layer. Using a single curing step reduces the thermal exposure of the substrate, which could result in stress. Moreover, curing is a process wherein a polymer may be cross-linked. The use of a single curing step allows crosslinking between the consecutively applied layers.

An advantage of the extension of the optically transparent structure 22a-c on both the first side 11 and the second side 12 is that is functions as an encapsulation for the thin and fragile semiconductor substrate 10. Such two-side encapsulation not merely is a protection against formation of cracks and breakage, but also exerts a similar stress on both sides, minimizing the risk of warpage.

Preferably, the optically transparent structure comprises a first main material. Use of a plurality of materials appears to lead to a more complex situation for optimizing optical transparency, adhesion problems as well as stability against processing agents. Nonetheless, in case two consecutive layers are applied by means of different processing (such as coating and moulding, or coating and printing), different materials may be necessary. Such materials are suitably polymer materials. It will therefore be understood, that a different material may alternatively be a differently engineered material, such as a copolymer or another copolymer, a material with a different molecular weight distribution and/or different molecular weight, a chemically modified materials or even a blend rather than a pure polymer.

Suitable optically transparent materials include, polyamides, polyesters, polyimides, polyacrylates, polymethyl-methacrylates, polycarbonates, epoxides, polysiloxanes and other Si-based polymers. One suitable example is for instance a PI 115A Durimide™ from Fujifilm that is spincoatable in a layer thickness of for instance 10 μm. Other suitable materials are known per se for instance from the fields of semiconductor packaging (transparent moulding compounds), liquid crystalline displays.

Preferably, the optically transparent structure comprises a compliant material. Such a compliant material is most suitably a first layer in contact with the underlying antireflection coating. The compliant material may be chosen as a typical primer material for adhesion promotion, such as for instance VM652 primer, but alternatively be a rubbery material with a large coefficient of thermal expansion. In this manner, the expansion of the semiconductor substrate 11 is at least partially decoupled from the expansion of the optically transparent structure 22, that may be stiff and hardened after curing. A significant expansion of the compliant material leads thereto that the optically transparent structure will—slightly—move upwards, and therewith prevents stress that could otherwise occur within valleys on the texturized first side 11. One example of a compliant material is for instance a polydimethylsiloxane, as is well known in the art.

The height of the optically transparent structure may be chosen differently in different implementations. In a first and most preferred implementation, the height is chosen such that a subsequently deposited contact structure is completely confined within the optically transparent structure. In an alternative implementation, the height is chosen such that the contact structure (and/or any conductors) metal stack will be plated partly over the transparent layer. The latter provides an option to control metal contact area independent from the width of conductors. Reduction of contact area to the solar cell is beneficial in order to increase the area without recombination of charge carriers that has a negative impact on the cell efficiency. Good line resistance however requires comparatively broad width of the conductors. It will be understood that such difference in width between the contact structures and the conductors may also be achieved in a two-level optically transparent structure.

Another alternative implementation comprises depositing a very thin optically transparent structure. The thickness of the optically transparent structure according to this embodiment is for instance less than 50 nm, more preferably between 1 and 10 nm. The aim of such structure is primarily to fill up any gaps and voids in an underlying layer, particularly an underlying passivation layer, such as a silicon-nitride layer. A further aim is then to provide a sealing layer, so as to protect against ghost plating. Such implementation is advantageous when already a quite good insulating layer is present, which only needs an additional cover to protect from ghost plating. The preferred very thin thickness of between 1 and 10 nanometers moreover allows that, a laser step can locally ablate both the optical transparent structure as well as the silicon nitride layer, either in a single step or in a plurality of consecutive steps, suitably in one apparatus, and more suitably with different wavelengths.

FIG. 3 shows the semiconductor substrate 10 in a third stage after patterning the optically transparent structure 22, so as to form an aperture 30. Though not shown, channels running along the first side may be formed simultaneously. The patterning may be obtained in several manners. One suitable manner, for patterning at least one of the layers constituting the optically transparent structure, resides screen printing or inkjet printing the material such that patterned is created at the same time as layer application. Another manner of patterning is in the use of local heating, and more particularly by means of beam-shaped irradiation, for instance irradiation with a light source, such as a laser. In FIG. 3 only one aperture 30 is indicated, but it will be understood by the skilled person that typically a plurality of apertures 30 will be created. One advantage of the use of beam-shaped irradiation is that well defined channels can be created in the transparent material. A printed layer may not have sufficiently well defined channels. Photolithography may not provide the required low cost of ownership, in view of the additional required usually expensive photo-sensitive additives. Moreover, the photo-sensitive material will most probably not stay stable during 25 years operation under solar irradiation in the transparent structure. Beam-shaped irradiation is suitable, because it allows very good control of the resulting shape of the channel and can remove the transparent material locally without leaving residues on the semiconductor substrate.

Suitably, the underlying passivation layer 16 is patterned after creating of the aperture 30. This patterned is suitably carried out in known manner, for instance by using the same laser or a second laser within the same system or with a selective wet chemical etchant, such as a hydrofluoric acid solution (HF). Cleaning treatments may further be applied, for instance a plasma treatment (known as descum), for removal of remaining small residues.

FIG. 4 shows the solar cell with the resulting contact structure that is obtained after deposition of suitable materials. The contact structure suitably comprises a seed layer (not-shown), a barrier layer 41, a conductor layer 42 and a capping layer 43. The barrier layer 41 suitably contains nickel (Ni) in a thickness for instance 1-3 microns. The conductor layer 42 suitably contains copper (Cu) in a thickness of for instance 5-10 microns. The capping layer 43 suitably contains tin (Sn), for instance in a thickness of 1-3 microns. Alloys could be used rather than pure metals, and alloys could be formed at the interface between the barrier layer 41, the conductor layer 42 and/or the capping layer 43.

A seed layer may be deposited in the aperture 30 and/or other areas using a conventional selective deposition process, such as an electroless plating or selective CVD deposition process. An example of electroless deposition process that may be used to grow a seed layer on a doped silicon region comprises the exposure of the substrate to a buffered oxide etch (BOE) solution to form a silicon hydride layer on the substrate during a pretreatment process, following by the deposition of a metal silicide layer and optionally the deposition of a first metal layer. The silicon hydride layer is also known per se as a hydrogen terminated silicon surface. The metal silicide layer herein suitably contains cobalt, nickel, tungsten, alloys thereof or combinations thereof and may be deposited by exposure of the substrate to a deposition solution during an electroless deposition process. Such deposition solution for instance contains a solvent (e.g. acetonitrile or propylene glycol monomethyl ether) and a complexed metal compound, such as cobalt tetracarbonyl, nickel dicyclooctadiene, or tungsten carbonyl.

In another embodiment, the seed layer may be selectively formed by use of an inkjet, rubber stamping, or any technique for the pattern wise deposition (i.e., printing) of a metal containing liquid or colloidal media on the surface of the substrate. After depositing the metal containing liquid or colloidal media on the surface of the substrate it is generally desirable to subsequently perform a thermal post treatment to remove any solvent and promote adhesion of the metal to the substrate surface. Particularly, the use of inkjet printing appears suitable for provision of a seed layer (or at least certain droplets of seed) within the aperture 30 defined within the optically transparent structure 22.

In general, the seed layer may contain a conductive material such as a pure metal, metal alloy or other conductive material. In one embodiment, the seed layer contains one or more metals selected from the group consisting of nickel (Ni), cobalt (Co), titanium (Ti), tantalum (Ta), rhenium (Rh), molybdenum (Mo), tungsten (W), palladium (Pd), platinum (Pt) and ruthenium (Ru). It is desirable to select a deposition process and a metal that forms a good electrical contact, or ohmic contact, between the doped silicon region (e.g., n-type region 13) and the deposited seed layer.

A barrier layer 41 is selected so that it acts as a barrier to the diffusion of a metal in the subsequently formed conductor 42 during subsequent processing steps. This barrier layer 41 may be identical to the seed layer or different therefrom. For example, the barrier layer 41 may contain one or more metals or metal alloys selected from the group consisting of nickel (Ni), cobalt (Co), titanium (Ti), their silicides, titanium tungsten (TiW), titanium nitride (TiN), tantalum (Ta), tantalum nitride (TaN), molybdenum (Mo), tungsten (W), tungsten silicide (WSi), molybdenum silicide (MoSi), and ruthenium (Ru). The formation of the barrier layer may be enhanced by providing activation materials like palladium (Pd), platinum (Pt) or gold (Au) prior to the barrier layer deposition step. In one embodiment, the thickness of the barrier layer 41 may be between about 0.1 micrometers (μm) and about 3 μm. The barrier layer 41 is suitably applied by electroplating or electroless deposition. Vapor deposition is an alternative, which allows coverage of walls of the aperture 30 as well.

A conductor layer 42 is thereafter deposited, suitably by means of electroplating. A most preferred material is copper (Cu), but alternatives, including copper alloys and silver are not excluded. The conductor layer suitably has a thickness of 3-30 microns, for instance 5-10 microns. The electroplating is suitably carried out with an electrolyte solution, in otherwise known manner.

An interface layer 43 is suitably provided on top of the conductor layer 42, so as to provide an appropriate interface to any further conductive layers deposited subsequently, for instance for the definition of conductors running over or in channels within the optically transparent structure. The interface layer 43 moreover is a shield encapsulating the conductor layer so as to minimize diffusion. The interface layer 43 could also be applied only after intermediate steps have been carried out so as to form said conductors (not shown). A suitable material for the interface layer 43 is for instance nickel (Ni), gold (Au), silver (Ag) and tin (Sn), which moreover may form intermetallic compounds (e.g alloys).

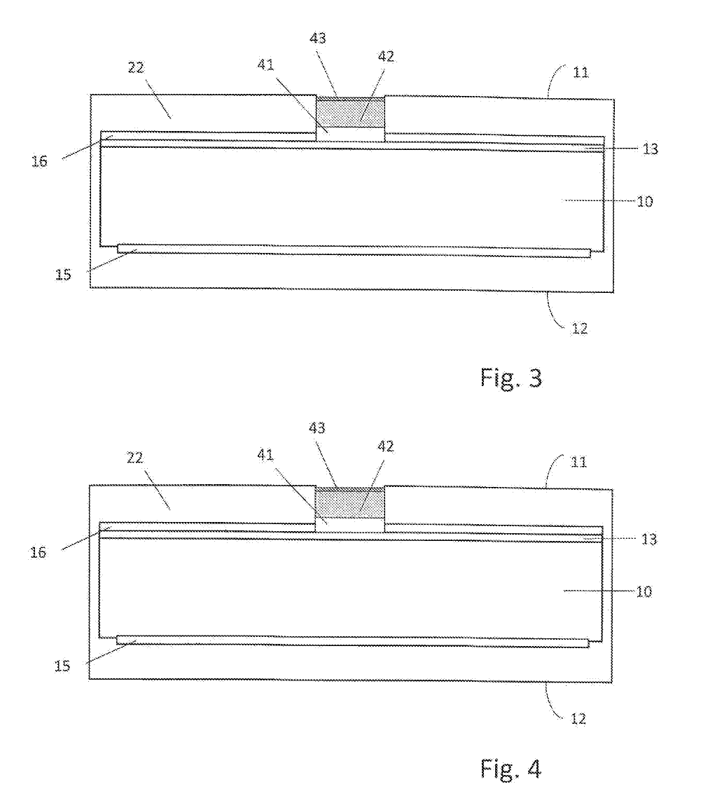

FIG. 5 shows a second embodiment of the invention, wherein the optically transparent structure 22 is not merely patterned at the first side 11 of the substrate, but also at the second side 12 of the substrate 10. This is beneficial to increase the transmission of light into the solar cell, and therewith to increase the cell efficiency. Back side reflecting structures, such as white paint layers, may then be suitably implemented on assembly level, i.e. in the solar panel, rather than directly on device level.

The contact structure at the second side 12 comprises in one embodiment a barrier layer 61, a conductor layer 62 and an interface layer 63. The materials used for the contact structure on the second side 12 may be the same or different as those in the contact structure on the first side 11. In the event that the materials are the same, both contact structures are suitably deposited simultaneously, but this is not necessary. In the event that the materials are different, the formation of the apertures is suitably also carried out separately.

This embodiment furthermore allows plating of specific type solar cells, such as bi-facial cells and heterojunction cells. In such cells, the second contact region 15 is for instance a combination of an amorphous intrinisic- and p-type silicon and a conductor such as indium tin oxide (ITO) or zinc oxide (ZnO). The first contact region 13 in for instance a combination of amorphous intrinsic and n-type silicon and a conductor such as ITO.

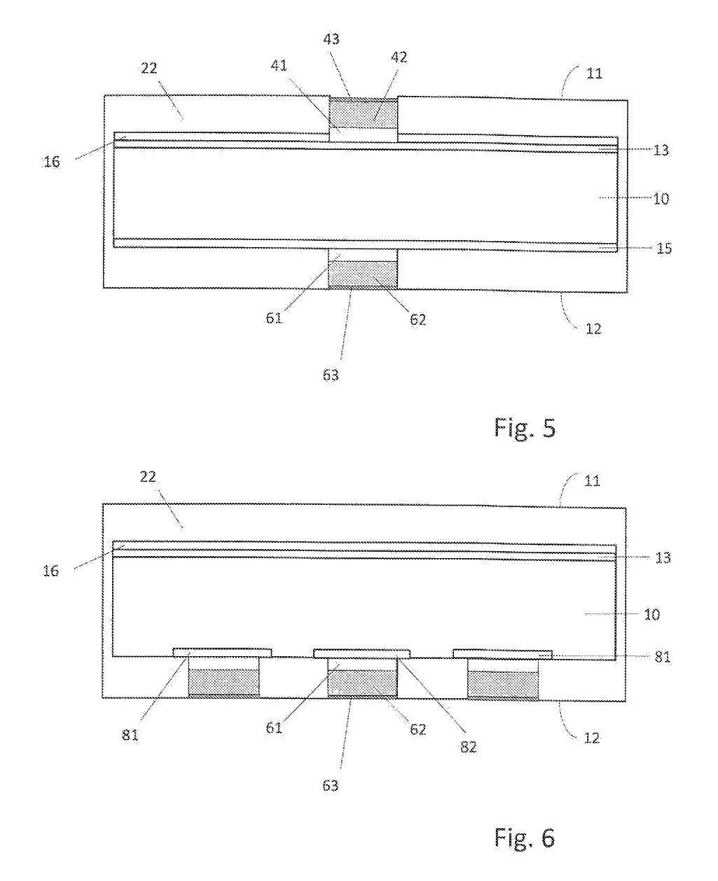

FIG. 6 shows in cross-sectional diagrammatical view a third embodiment of the invention.

Herein, a solar cell is shown with an inter-digitated back contact structure, also known as an IBC type cell. The IBC type cell comprises inter-digitated contacts on the second, rear side 12. The semiconductor substrate 10 is thereto provided with first regions 81 and second regions 82 which are doped with charge carriers of a first and a second conductivity type respectively, i.e. n+ and p+ or alternatively p+ and n+. Doping levels are well-known to the skilled person per se. A further contact region 13 is present at the first side 11 of the substrate 10. According to the design of the IBC cell, the further contact region 13 is not connected with any contact structures, or at least no significant number of contact structures is provided. However, contact structures are applied to the first and second contact regions 81, 82 at the second side.

Whereas FIG. 6 merely shows a passivation layer 16 at the first side 11, it is advantageous, if a further passivation layer is present at the second side 12. Such second side passivation is for instance a PECVD type nitride layer. The first side passivation layer 16 may comprise PECVD or LPCVD silicon nitride layer.

An optically transparent structure 22 is shown to encapsulate the solar cell device, but this is not necessary. According to the inventors, an optically transparent structure extending merely at the second side 12 may be sufficient. Moreover, while the optically transparent structure 22 is shown here as a single layer, it may well be defined as a multilayer structure 22, wherein the first layer is a sealing material for any passivation layer on the second side 12. The second layer of the structure then defines spaces for the deposition of conductors. The second layer does not need to be continuous, but may have the form of protruding walls. The surface area of any spaces formed in the first layer may well be smaller than the surface area of any spaces in the second layer. In the present embodiment, a three-layer conductor is shown on top of the contact regions 81, 82. The interface layer 63 herein effectively defines a terminal for coupling to a contact on a carrier, or for coupling to a further semiconductor device. The barrier layer 61, and the conductor layer 62 serve to couple the contact region to the interface layer 63 acting as a terminal.

While in the present cross-sectional view the barrier layer 61 has the same diameter as the conductor layer 62 and the interface layer 63, this is not necessarily the case. Contrarily, the use of an optically transparent structure 22 with a first layer and a second layer may be exploited so that the diameter of the barrier layer 61 is reduced relative to the diameter of the conductor layer 62 and/or the diameter of the interface layer. Such a reduction of the diameter of the barrier layer 61 is effectively due to a reduction of the diameter of the aperture in the corresponding layer of the optically transparent structure. One of its advantages is that the dimensions of the contact regions 81, 82 may be reduced as well. The dimensions of the contact regions 81, 82 are effectively coupled to the diameter of the barrier layer 61, in that the contact regions are to extend below the first layer of the optically transparent structure. Reduction of the dimensions of the contact regions 81, 82 is beneficial, as it will result in less recombination and higher cell efficiency.

While the present cross-sectional view may suggest that the shape of the contact regions 81, 82 substantially corresponds to that of the conductors 62, this is not necessarily the case. Rather, the contact regions 81, 82 may be faces, for instance round or square, whereas the conductors 62 may extend along the second side 12 to have a fingered-shape.

In the embodiment that the optically transparent structure is applied on both sides, this structure is preferably maintained on both sides in the final product, i.e. removal of the structure after the provision of the contact structure on that side is not foreseen.

Alternatively, it is not excluded that the optically transparent structure is at least partially removed. This may be suitable so as to obtain a hermetic sealing of the conductor material, to improve adhesion of the encapsulant to the solar cell during assembly, and/or to improve adhesion of the contact structure to any electrically conducting means, such as electrically conducting adhesive or solder to the assembly.

One implementation of such at least partial removal of the optically transparent structure 22 resides in the removal of an upper layer thereof. Such removal could for instance be done after the provision of the contact structures and/or any conductors. A first advantage is that the interface layer 43 could then surround the contact structure as much as possible. A second advantage is that any visible damages on the optically transparent structure 22 may be removed. Such visible damages could for instance result from laying down the solar cell on its optically transparent structure 22 at the first side 11 during processing of the second side 12.

Such removal of an upper layer may be facilitated by means of a sacrificial layer being provided below such upper layer. One suitable sacrificial layer is for instance a UV-sensitive glue,.

An alternative or additional implementation of such at least partial removal of the optically transparent structure, resides in carrying out a second patterning step. This is most suitably done after definition of the conductor layer 42, and particularly before deposition of the interface layer 43. Such second patterning step is most suitably carried out to expose side faces of the conductor layer 42. The subsequently deposited interface 43 may then be deposited both on top and sidewise to the conductor layer 42 in the contact structure, so as to encapsulate the conductor layer 42. More particularly, such patterning may be carried around a contact structure, so as to remove a ring-shaped or substantially ring-shaped portion of the optically transparent structure. This removal process is most advantageously carried out by means of application of beam-shaped local heating, particularly from a laser source. Other methods for such second patterning step, for instance with the help of a sacrificial layer, are envisageable.

### NRS IN FIGURES

10 semiconductor substrate
11 first side of semiconductor substrate, also front side where light is irradiated
12 second side of semiconductor substrate, also rear-side of the solar cell
13 first contact region
14 Substrate side or edge of the cell
15 Second contact region on the second side of the substrate
16 passivation layer
22 optically transparent structure
22a portion of the optically transparent structure on the first side 11
22b portion of the optically transparent structure on the second side 12
22c portion of the optically transparent structure along the edge 14
30 Aperture in the optically transparent structure 22
41 barrier layer of a contact structure on the first side 11
42 conductor layer of the contact structure on the first side 11
43 interface layer of the contact structure on the first side 11
61 barrier layer of the contact structure on the second side 12
62 conductor layer of the contact structure on the second side 12
63 interface layer of the contact structure on the second side 12
81 first contact region, particularly p+ emitter region, of the IBC solar cell
82 second contact region, particularly n+ base region, of the IBC solar cell

1. A method of manufacturing a solar cell comprising a solar cell device with an optically transparent structure, through which a contact structure extends to a first contact region in a semiconductor body of the solar cell device, which method comprises the steps of:
providing the solar cell semi-manufactured device having a first side and an opposed second side, which first side is intended for capturing incident light and which second side is intended for assembly to a carrier, which solar cell device is provided with a passivation layer on at least one of the first and the second side;
applying the optically transparent structure of electrically insulating, curable polymer material on top of the passivation layer to the first side and to the second side, so as to constitutes an encapsulation, wherein the application of the optically transparent structure comprises depositing a first layer, which acts as a sealing material for the underlying passivation layer,
curing the polymer material of the optically transparent structure, which structure is patterned to form an aperture, and is an integral part of and a protection for the solar cell device,
patterning the underlying passivation layer after deposition of the first layer, so as to expose the first contact region, and
providing the contact structure of electrically conducting material in said aperture by means of electrochemical deposition, which contact structure comprises a barrier layer, a conductor layer and an interface layer.

2. (canceled)

3. The method as claimed in claim 1, wherein the optically transparent structure and/or its first layer is patterned after its deposition.

4. The method as claimed in claim 3, wherein the patterning occurs by means of locally heating said optically transparent structure.

5. The method as claimed in claim 4, wherein the local heating is carried out by means of irradiating with a light source such as a laser.

6. The method as claimed in claim 1, wherein the passivation layer and the first layer are patterned with a single apparatus.

7. The method as claimed in claim 6, wherein the first layer and the passivation layer are consecutively patterned with different wavelengths.

8. The method as claimed in claim 1, wherein the application of the optically transparent structure further comprises depositing a second layer with a thickness in a micrometer range.

9. The method as claimed in claim 8, wherein said second layer is patterned with a different pattern than the first layer.

10.-15. (canceled)

16. The method as claimed in claim 1, further comprising providing conductor means electrically coupling the contact structure to at least one terminal and/or further contact of the solar cell, said conductor means provision comprising forming an electrical conductor running over or in channels in said optically transparent structure and being connected to said contact structure.

17. The method as claimed in claim 16, wherein the electrical conductor extends from the first side to the second side of the solar cell device.

18. The method as claimed in claim 17, wherein the electrical conductor extends to a further contact at the second side of the solar cell.

19.-21. (canceled)

22. The method as claimed in claim 1, wherein the optically transparent structure comprises additives for enhancing optical transmission.

23. (canceled)

24. A solar cell comprising a solar cell device provided with a semiconductor body with a first contact region and a passivation layer thereon, which solar cell device is provided with a first side and an opposed second side, which first side is for capturing incident light and which second side is for assembly to a carrier, wherein the solar cell further comprises:
a patterned optically transparent structure of insulating, cured polymer material, which is present on the passivation layer on at least the first side of the solar cell device, wherein a first layer of the optically transparent structure constitutes a sealing material of the passivation layer, and wherein the optically transparent structure constitutes an encapsulation and extends on both the first side and the second side of the solar cell device;
a contact structure connected to the first contact region, which comprises a barrier layer, a conductor layer and an interface layer, which contact structure extends through the patterned optically transparent structure and through the passivation layer and is electrochemically deposited.

25. (canceled)

26. The solar cell as claimed in claim 24, further comprising a first terminal coupled to the contact structure through conductor means, which comprises a conductor running over the optically transparent structure or in channels in said optically transparent structure at the first side of the solar cell device.

27. The solar cell as claimed in claim 24, further comprising a further contact at the second side of the solar cell device, which further contact is coupled to the contact structure through conductor means, which comprises a conductor running over the optically transparent structure or in channels in said optically transparent structure at the first side of the solar cell device and extending to the second side of the solar cell device.

28. The solar cell as claimed in claim 24, wherein the semiconductor body comprises at least one amorphous semiconductor layer, so as to define a solar cell of for instance a bifacial cell type or a HIT cell type.

29. The solar cell as claimed in claim 24, wherein the solar cell device is of the inter-digitated back contact (IBC) or hetero junction back-contact (HJ-BC) type and comprises inter-digitated first and second terminals at the second side, the first terminals being coupled to first contact regions in the semiconductor body, said first contact regions being doped with charge carriers of a first conductivity type, which second terminals are coupled to second contact regions in the semiconductor body, the second contact regions being doped with charge carriers of a second conductivity type opposed to the first conductivity type.

30. The solar cell as claimed in claim 24, wherein the solar cell device is of the thin-film type (CdTe, CIGS, etc).

31-40. (canceled)

41. The solar cell as claimed in claim 24, wherein the conductor comprises copper or a copper alloy.

42. A method of manufacturing a solar cell comprising a solar cell device with an optically transparent structure, through which a contact structure extends to a first contact region in a semiconductor body of the solar cell device, which method comprises the steps of:
providing the solar cell semi-manufactured device having a first side and an opposed second side, which first side is intended for capturing incident light and which second side is intended for assembly to a carrier, which solar cell device is provided with a passivation layer on at least one of the first and the second side;
applying the optically transparent structure of electrically insulating, curable polymer material on top of the passivation layer, wherein the application of the optically transparent structure comprises depositing a first layer, which acts as a sealing material for the underlying passivation layer,
curing the polymer material of the first layer of the optically transparent structure, which first layer is patterned to form an aperture, wherein the optically transparent structure is an integral part of and a protection for the solar cell device,
patterning the underlying passivation layer after deposition of the first layer, so as to expose the first contact region, and
providing the contact structure of electrically conducting material in said aperture by means of electrochemical deposition, which contact structure comprises a barrier layer, a conductor layer and an interface layer.
